(19) United States
(12) Patent Application Publication
(10) Pub. No.: US 2009/0134450 A1
(43) Pub. Date: May 28, 2009

(54) Tunneling insulating layer, flash memory device including the same, memory card and system including the flash memory device, and methods of manufacturing the same

(75) Inventors: Chul-sung Kim, Seongnam-si (KR); Si-young Choi, Seongnam-si (KR); Bon-young Koo, Suwon-si (KR); Ki-hyun Hwang, Seongnam-si (KR); Young-Jin Noh, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/153,686

(22) Filed: May 22, 2008

(30) Foreign Application Priority Data
Nov. 28, 2007 (KR) 10-2007-0121998

(51) Int. Cl. H01L 29/788

(52) U.S. Cl. 257/325; 257/649; 257/E29.3

(57) ABSTRACT

Provided is a tunneling insulating layer, a flash memory device including the same that increases a program/erase operation speed of the flash memory device and has improved data retention in order to increase reliability of the flash memory device, a memory card and system including the flash memory device, and methods of manufacturing the same. A tunneling insulating layer may include a first region and a second region on the first region, wherein the first region has a first nitrogen atomic percent, the second region has a second nitrogen atomic percent, and the second nitrogen atomic percent is less than the first nitrogen atomic percent. The flash memory device according to example embodiments may include a substrate including source and drain regions and a channel region between the source and drain regions, the tunneling insulating layer on the channel region, a charge storage layer on the tunneling insulating layer, a blocking insulation layer on the charge storage layer, and a gate electrode on the blocking insulation layer.

### PRIORITY STATEMENT

This application claims priority under U.S.C. §119 to Korean Patent Application No. 10-2007-0121998, filed on Nov. 28, 2007, in the Korean Intellectual Property Office (KIPO), the entire contents of which are incorporated herein by reference.

### BACKGROUND

1. Field

Example embodiments relate to a tunneling insulating layer, a flash memory device including the same, a memory card and a system including the flash memory device, and methods of manufacturing the same. Other example embodiments relate to a tunneling insulating layer, a flash memory device that may increase a program/erase operation speed of the flash memory device and has improved data retention, a memory card and a system including the flash memory device, and methods of manufacturing the same.

2. Description of the Related Art

Among semiconductor memory devices, non-volatile memory devices retain stored data even if the power supply is interrupted. In recent years, owing to the increased demand for compact portable electronic products, e.g., portable multimedia reproduction devices, digital cameras, and personal digital assistants (PDAs), research into high-capacity highly-integrated non-volatile memory devices in compact portable electronic products has rapidly progressed. The non-volatile memory devices may be classified into programmable read-only memories (PROMs), erasable and programmable read-only memories (EPROMs), and electrically erasable and programmable read-only memories (EEPROMs). An example of the non-volatile memory device may be a flash memory device.

The flash memory device performs an erase operation and a rewrite operation in block units. Also, because the flash memory device is capable of higher integration and improved data retention characteristics, the flash memory device may function as a main memory in a system and may be applied to an ordinary dynamic random access memory (DRAM) interface. Furthermore, the flash memory device may have both higher integration and higher capacity and may be inexpensively fabricated, so that the flash memory device may be used as a subsidiary storage device in place of a conventional hard disk.

A cell transistor of a conventional flash memory may include a tunneling insulating layer disposed on a semiconductor substrate, a charge storage layer, a blocking insulating layer, and a control gate that may be stacked sequentially. The flash memory device performs a write operation using a hot electron injection or Fowler-Nordheim tunneling (F-N tunneling) mechanism, while the flash memory device performs an erase operation through the F-N tunneling mechanism.

Cell characteristics of the flash memory device depend on the thickness of the tunneling insulating layer, a contact area between the charge storage layer and the semiconductor substrate, a contact area between the charge storage layer and the control gate, or the thickness of the blocking insulating layer. The cell characteristics of the flash memory device may include program speed, erase speed, the distribution of program cells, and the distribution of erase cells. Also, other characteristics related to the reliability of cells of the flash memory device may be program/erase endurance and data retention.

In particular, as a design rule is reduced due to recent higher integration of flash memory devices, undesired coupling interference between adjacent charge storage layers may increase, and a coupling rate, which is a voltage transmission performance of the charge storage layer with respect to the control gate, may be reduced. Consequently, program and erase operation speeds of flash memory devices may decrease.

To solve this problem, in a process of manufacturing a flash memory device having a size less than or equal to 50 nm, flash memory devices may include a charge trap layer that uses an insulating material as a charge storage layer instead of using a floating gate that is a conductor. For example, the insulating material for storing charges may be a silicon-oxide-nitride-oxide-silicon (SONOS) or a metal-oxide-nitride-oxide-silicon (MONOS) that use a Si₃N₄ film. When charges are trapped in the charge trap layer, a threshold voltage may be shifted. Flash memory devices having such a structure may be called charge trap flash (CTF) memory devices.

Program and erase operation characteristics of such a SONOS flash memory device may vary according to a tunneling current of electrons and holes. In general, when the tunneling insulating layer is formed relatively thin, the operation characteristics of the flash memory device may be improved. However, data retention may be reduced due to an increase in leakage current. On the other hand, when the tunneling insulating layer is formed relatively thick, a program/erase operation speed of the flash memory device may decrease.

### SUMMARY

Example embodiments provide a tunneling insulating layer and a flash memory device including the same that may increase a program/erase operation speed and may have improved data retention so as to improve reliability and methods of manufacturing the same. Example embodiments also provide a memory card and system including the flash memory device and methods of manufacturing the same.

According to example embodiments, a tunneling insulating layer may include a first region and a second region on the first region, wherein the first region has a first nitrogen atomic percent, the second region has a second nitrogen atomic percent, and the second nitrogen atomic percent is less than the first nitrogen atomic percent.

The first nitrogen atomic percent may be in the range of about 1 to about 30%. The first nitrogen atomic percent may be in the range of about 5 to about 15%. The second nitrogen atomic percent may be in the range of about 0.01 to about 5%. The first region may have a height that may be less than or equal to a half of the height of the tunneling insulating layer. The first region may have a height that may be less than or equal to a third of the height of the tunneling insulating layer.

The first region may be a single layer including silicon oxynitride (SiON). The first region may be formed of multiple layers including at least two materials selected from the group consisting of silicon oxide (SiO₂), silicon nitride (Si₃N₄), and silicon oxynitride (SiON). The second region may include one selected from the group consisting of silicon oxide (SiO₂) and silicon oxynitride (SiON), or a combination of two or more materials. One or both of the first region and the second region may include an oxide film including at least one of a chemical vapor deposition (CVD) oxide film, a CVD nitride film, a thermal oxide film, and a thermal nitride film.

According to example embodiments, a flash memory device may include a substrate including source and drain regions and a channel region between the source and drain regions, the tunneling insulating layer of example embodiments on the channel region, a charge storage layer on the tunneling insulating layer; a blocking insulation layer on the charge storage layer; and a gate electrode on the blocking insulation layer.

An energy band gap of the tunneling insulating layer may be greater than an energy band gap of the charge storage layer. The charge storage layer may include a charge trap layer for trapping charges. The charge trap layer may include at least one selected from the group consisting of a silicon oxide (SiO₂) layer, a silicon oxynitride (SiON), a silicon nitride (Si₃N₄) layer, Si rich nitride (SRN) layer, aluminum oxide (Al₂O₃) layer, an aluminum nitride (AlN) layer, a hafnium oxide (HfO₂) layer, a hafnium silicon oxide (HfSiO) layer, a hafnium silicon oxynitride (HfSiON) layer, a hafnium oxynitride (HfON) layer, a hafnium aluminum oxide layer (HfAlO), a zirconium oxide (ZrO₂) layer, a tantalum oxide (Ta₂O₃) layer, a hafnium tantalum oxide (HfTaₓO_{y}) layer, a lanthanum oxide (LaO) layer, lanthanum aluminum oxide (LaAlO) layer, a lanthanum hafnium oxide layer (LaHfO), and a combination thereof. The charge trap layer may further include quantum dots. The quantum dots may include at least one selected from the group consisting of silicon-quantum dots, germanium-quantum dots, tin-quantum dots, and gold-quantum dots, or a combination thereof.

The blocking insulation layer may include at least one selected from the group consisting of a silicon oxide (SiO₂) layer, a silicon oxynitride (SiON), a silicon nitride (Si₃N₄) layer, Si rich nitride (SRN) layer, aluminum oxide (Al₂O₃) layer, an aluminum nitride (AlN) layer, a hafnium oxide (HfO₂) layer, a hafnium silicon oxide (HfSiO) layer, a hafnium silicon oxynitride (HfSiON) layer, a hafnium oxynitride (HfON) layer, a hafnium aluminum oxide layer (HfAlO), a zirconium oxide (ZrO₂) layer, a tantalum oxide (Ta₂O₃) layer, a hafnium tantalum oxide (HfTaₓO_{y}) layer, a lanthanum oxide (LaO) layer, lanthanum aluminum oxide (LaAlO) layer, a lanthanum hafnium oxide layer (LaHfO), and a combination thereof.

The gate electrode may include one selected from the group consisting of poly-silicon, Al, Ru, TaN, TiN, W, WN, HfN, and WSi, or a combination thereof. The substrate may include one selected from the group consisting of silicon, silicon-on-insulator, silicon-on-sapphire, germanium, silicon-germanium, and gallium-arsenide, or a combination thereof.

According to example embodiments, a memory card may include a memory including the flash memory device according to example embodiments, and a controller configured to control the memory, including sending and receiving data to and from the memory. According to example embodiments, a system may include a memory including the flash memory device according to example embodiments, a processor configured to send and receive data to and from the memory via a bus, and an input/output device configured to send and receive data to and from the bus.

According to example embodiments, a method of manufacturing a tunneling insulating layer may include forming a second region on a first region of the tunneling insulating layer, wherein the first region has a first nitrogen atomic percent, the second region has a second nitrogen atomic percent, and the second nitrogen atomic percent is less than the first nitrogen atomic percent.

According to example embodiments, a method of manufacturing a flash memory device may include providing a substrate including source and drain regions, forming a channel region between the source and drain regions of the substrate, forming the tunneling insulating layer according to example embodiments on the channel region, forming a charge storage layer on the tunneling insulating layer, forming a blocking insulation layer on the charge storage layer, and forming a gate electrode on the blocking insulation layer.

According to example embodiments, a method of manufacturing a memory card may include providing a memory including the flash memory device manufactured according to example embodiments, and configuring a controller to control the memory, including sending and receiving data to and from the memory.

According to example embodiments, a method of manufacturing a system may include providing a memory including the flash memory device manufactured according to example embodiments, configuring a processor to send and receive data to and from the memory via a bus, and configuring an input/output device to send and receive data to and from the bus.

### BRIEF DESCRIPTION OF THE DRAWINGS

Example embodiments will be more clearly understood from the following detailed description taken in conjunction with the accompanying drawings. FIGS. 1-8 represent non-limiting, example embodiments as described herein.

FIG. 1 is a schematic cross-sectional view of a flash memory device according to example embodiments;

FIG. 2 is a graph illustrating a nitrogen atomic percentage in a tunneling insulating layer of the flash memory device according to example embodiments illustrated in FIG. 1;

FIG. 3 illustrates an energy band model of the flash memory device according to example embodiments illustrated in FIG. 1;

FIG. 4 illustrates an energy band model for describing a program operation of the flash memory device according to example embodiments illustrated in FIG. 1;

FIG. 5 illustrates an energy band model for describing an erase operation of the flash memory device according to example embodiments illustrated in FIG. 1;

FIG. 6 is a graph illustrating characteristics of a gate bias and a drain current after applying a voltage stress to a flash memory device including a floating gate having a nitrogen atomic percent equal to or greater than 5% according to a comparative example with respect to example embodiments;

FIG. 7 is a schematic view of a memory card according to example embodiments; and

FIG. 8 is a schematic view of a system according to example embodiments.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Reference will now be made in detail to example embodiments, examples of which are illustrated in the accompanying drawings. However, example embodiments are not limited to the embodiments illustrated hereinafter, and the embodiments herein are rather introduced to provide easy and complete understanding of the scope and spirit of example embodiments. In the drawings, the thicknesses of layers and regions are exaggerated for clarity.

It will be understood that when an element, such as a layer, a region, or a substrate, is referred to as being “on,” “connected to” or “coupled to” another element, it may be directly on, connected or coupled to the other element or intervening elements may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “above,” “upper,” “beneath,” “below,” “lower,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “above” may encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but may be to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes may be not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

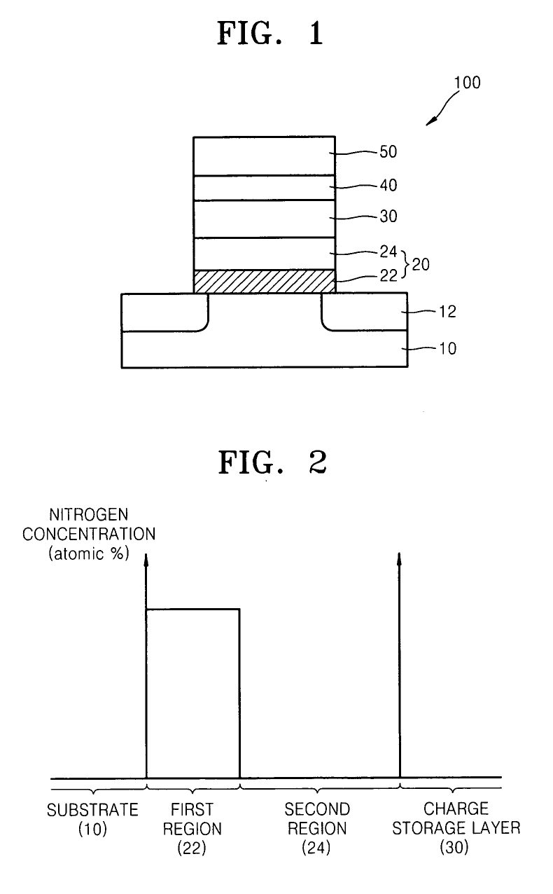

FIG. 1 is a schematic cross-sectional view of a flash memory device 100 according to example embodiments. Referring to FIG. 1, the flash memory device 100 may include a stack structure disposed on a substrate 10 including active regions 12 doped with conductive impurities (hereinafter, impurity regions 12). The stack structure may include a tunneling insulating layer 20, a charge storage layer 30, a blocking insulation layer 40, and a control gate 50 that may be stacked sequentially. The stack structure may be formed by a conventional layer forming method and a conventional layer patterning method, except for matters specifically described in the specification.

The substrate 10 may be a semiconductor substrate, which includes, for example, one selected from silicon, silicon-on-insulator, silicon-on-sapphire, germanium, silicon-germanium, and gallium-arsenide. The impurity regions 12 may be used as source and drain regions and a channel region disposed between the source and drain regions. Although not shown in the drawings, the substrate 10 may include a device isolation layer, which may be obtained using a shallow trench isolation (STI) technique, and a well region, which may be formed using an ion implantation process.

The tunneling insulating layer 20 may be disposed on the substrate 10 and may contact the impurity regions 12. The tunneling insulating layer 20 may include a first region 22 having a first nitrogen atomic percent and a second region 24 having a second nitrogen atomic percent that may be lower than the first nitrogen atomic percent, wherein the second region 24 may be formed on the first region 22. A manufacturing method, components, and characteristics of the tunneling insulating layer 20 will be described later.

The charge storage layer 30 may be formed on the tunneling insulating layer 20, and may be a floating gate or a charge trap layer. When the charge storage layer 30 is a floating gate, the charge storage layer 30 may be formed by depositing polysilicon using a chemical vapor deposition (CVD) method, for example, a low pressure CVD (LPCVD) method using a SiH₄ or Si₂H₆ gas and a PH₃ gas. On the other hand, when the charge storage layer 30 is a charge trap layer, the charge storage layer 30 may be formed of a single layer or multiple layers including at least one selected from the group consisting of a silicon oxide (SiO₂) layer, a silicon oxynitride (SiON), a silicon nitride (Si₃N₄) layer, Si rich nitride (SRN) layer, aluminum oxide (Al₂O₃) layer, an aluminum nitride (AlN) layer, a hafnium oxide (HfO₂) layer, a hafnium silicon oxide (HfSiO) layer, a hafnium silicon oxynitride (HfSiON) layer, a hafnium oxynitride (HfON) layer, a hafnium aluminum oxide layer (HfAlO), a zirconium oxide (ZrO₂) layer, a tantalum oxide (Ta₂O₃) layer, a hafnium tantalum oxide (HfTaₓO_{y}) layer, a lanthanum oxide (LaO) layer, lanthanum aluminum oxide (LaAlO) layer, a lanthanum hafnium oxide layer (LaHfO), and a combination thereof.

Also, the charge storage layer 30 may include a plurality of quantum dots in order to increase integration of the flash memory device 100. Quantum dots generally denote atomic sized dots, however, manufacturing quantum dots with atomic sizes may be difficult. Accordingly, the quantum dots stated in the specification may also denote charge trap elements, e.g., nano-crystals, with sizes larger than the atomic size, for example, with diameters in the range of about 20 to about 30 nm. The quantum dots may be silicon-quantum dots, germanium-quantum dots, tin-quantum dots, or gold-quantum dots, and may be formed by a method well-known in the technical field. For example, after a metal ion is injected into an oxide film or a nitride film, the metal ion may be transformed into quantum dots with a predetermined or given size by using an appropriate thermal treatment. Alternatively, the quantum dots may be formed by forming a thin metal layer in an oxide film or a nitride film by CVD, stacking another oxide film or nitride film covering the metal layer on the resultant structure, and then performing a thermal treatment on the stacked structure.

The blocking insulation layer 40 may be formed on the charge storage layer 30, and may include at least one selected from the group consisting of a silicon oxide (SiO₂) layer, a silicon oxynitride (SiON), a silicon nitride (Si₃N₄) layer, Si rich nitride (SRN) layer, aluminum oxide (Al₂O₃) layer, an aluminum nitride (AlN) layer, a hafnium oxide (HfO₂) layer, a hafnium silicon oxide (HfSiO) layer, a hafnium silicon oxynitride (HfSiON) layer, a hafnium oxynitride (HfON) layer, a hafnium aluminum oxide layer (HfAlO), a zirconium oxide (ZrO₂) layer, a tantalum oxide (Ta₂O₃) layer, a hafnium tantalum oxide (HfTaₓO_{y}) layer, a lanthanum oxide (LaO) layer, lanthanum aluminum oxide (LaAlO) layer, a lanthanum hafnium oxide layer (LaHfO), and a combination thereof. The blocking insulation layer 40 may be formed of a single layer including two or more selected from the above material group or multiple layers which may be a stack of a plurality of layers each formed of at least one selected from the above material group. The blocking insulation layer 40 may be formed by physical vapor deposition (PVD), for example, atomic layer deposition (ALD), CVD, or a sputtering method. A thin-film deposition may be possible with ALD even at a relatively low temperature, and a composition ratio of a thin film may be more easily controlled.

The gate electrode 50 may be formed on the blocking insulation layer 40, and may include at least one selected from a group consisting of poly-silicon, Al, Ru, TaN, TiN, W, WN, HfN, and WSi, or a combination thereof. The gate electrode 50 may be formed by CVD, and may be electrically connected to a word line (not shown) or a control line (not shown). The above-described manufacturing method, layer structure, and materials of the stacked structure of the flash memory device 100, namely, the tunneling insulating layer 20, the charge storage layer 30, the blocking insulation layer 40, and the control gate 50, are examples, and example embodiments are not limited thereto. The tunneling insulating layer 20, which may be one of the features of example embodiments, will now be described in detail.

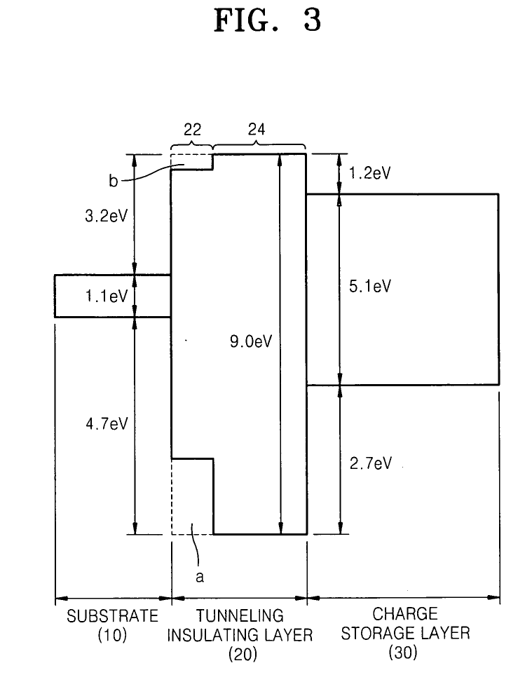

FIG. 2 is a graph illustrating a nitrogen atomic percent in the tunneling insulating layer 20 of the flash memory device 100 of FIG. 1. Referring to FIGS. 1 and 2, the tunneling insulating layer 20 may include the first region 22 adjacent to the substrate 10 and having the first nitrogen atomic percent, and the second region 24 formed on the first region 22 and having the second nitrogen atomic percent lower than the first nitrogen atomic percent. The first nitrogen atomic percent of the first region 22 may be in the range of about 1 to about 30%, for example, in the range of about 5 to about 15%. The second nitrogen atomic percent of the second region 24 may be in the range of about 0.01 to about 5%. In FIG. 2, the nitrogen atomic percent of the first region 22 is illustrated as a rectangle, however, in practice, the nitrogen atomic percent generally has a Gaussian function shape. As such, the relatively high nitrogen atomic percent of the first region 22 may enable charges to move in the flash memory device 100 during a programming/erasing operation. This will be described later in detail with reference to an energy band model illustrated in FIGS. 3 through 5.

The first region 22 may have a height that is less than or equal to half of the height of the tunneling insulating layer 20, for example, a height that may be less than or equal to a third of the height of the tunneling insulating layer 20. Also, the first region 22 may be a single layer including silicon oxynitride (SiON), or multiple layers including at least two materials selected from the group consisting of silicon oxide (SiO₂), silicon nitride (Si₃N₄), and silicon oxynitride (SiON). The second region 24 may include one selected from the group consisting of silicon oxide (SiO₂) and silicon oxynitride (SiON), or a combination thereof. One or both of the first region 22 and the second region 24 may include an oxide film including one or all of a CVD oxide film, a CVD nitride film, a thermal oxide film, and a thermal nitride film.

A method of forming the first region 22 and the second region 24 of the tunneling insulating layer 20 will now be described in detail. The tunneling insulating layer 20 may be formed by forming an oxide film, for example, a SiO₂ film, having a height in which the first region 22 and the second region 24 are formed, and performing thermal nitridation and annealing on the SiO₂ film in an atmosphere containing a nitride gas including nitrogen so as to accumulate nitrogen atoms in the first region 22.

Alternatively, the tunneling insulating layer 20 may be formed by performing plasma nitridation and annealing on the oxide film, for example, the SiO₂ film. The plasma nitridation may be an operation of accumulating nitrogen atoms of a radical state formed of plasma below a surface of the SiO₂ film, and nitriding the SiO₂ film. The nitrogen atoms accumulated below the surface of the SiO₂ film may react with silicon to cause Si—N bonding, and thus, a Si₃N₄ film may be formed. The nitrogen atoms may be separated from the silicon by annealing, move down towards the substrate 10, and may be accumulated in the first region 22. The accumulated nitrogen atoms may form the Si₃N₄ film by reacting with silicon or form a SiON film by reacting with silicon and oxygen.

Alternatively, the tunneling insulating layer 20 may be formed by a wet oxidation method. For example, in the wet oxidation method, an SiO film may undergo wet oxidation at a temperature in the range of about 700 to about 800° C., and an annealing process may be performed on the resultant SiO film in a nitrogen atmosphere at a temperature of about 900° C. for about 20 to about 30 minutes, thereby forming the tunneling insulating layer 20.

The SiO₂, Si₃N₄, or SiON film included in the first region 22 and/or the second region 24 of the tunneling insulating layer 20 may be formed using a conventional CVD method. Alternatively, the first region 22 and the second region 24 may be formed using a combination of the CVD method with at least one of a thermal oxidation method, an ALD method, a thermal nitridation method, a plasma nitridation method, and a wet oxidation method. The films of the first region 22 and/or the second region 24 may be formed as single layers or multiple layers.

However, the manufacturing method, the layer structure, and the material of the tunneling insulating layer 20 are examples, and example embodiments are not limited thereto. For example, the tunneling insulating layer 20 may be formed in a single-layered structure or a multiple-layered structure having different energy band gaps, and may be formed of one selected from the group consisting silicon oxide (SiO₂), a silicon oxynitride (SiON), a silicon nitride (Si₃N₄), hafnium oxide (HfO₂), a hafnium silicon oxide (HfSiO), aluminum oxide (Al₂O₃) zirconium oxide (ZrO₂), or a combination thereof.

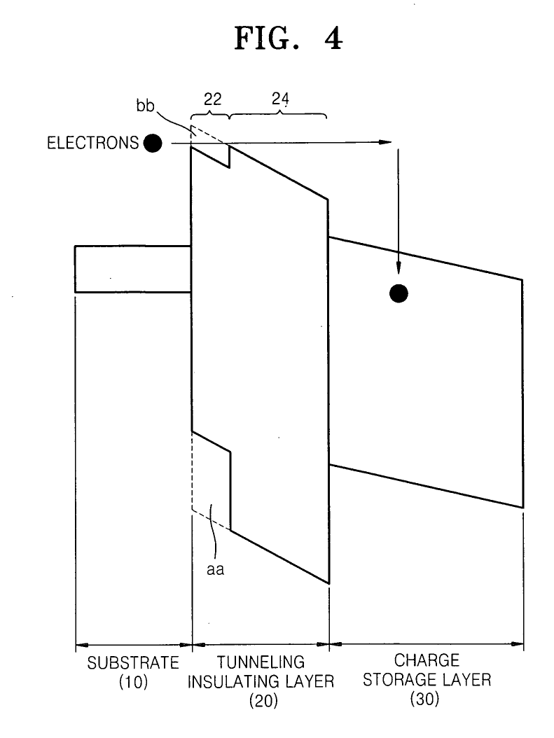

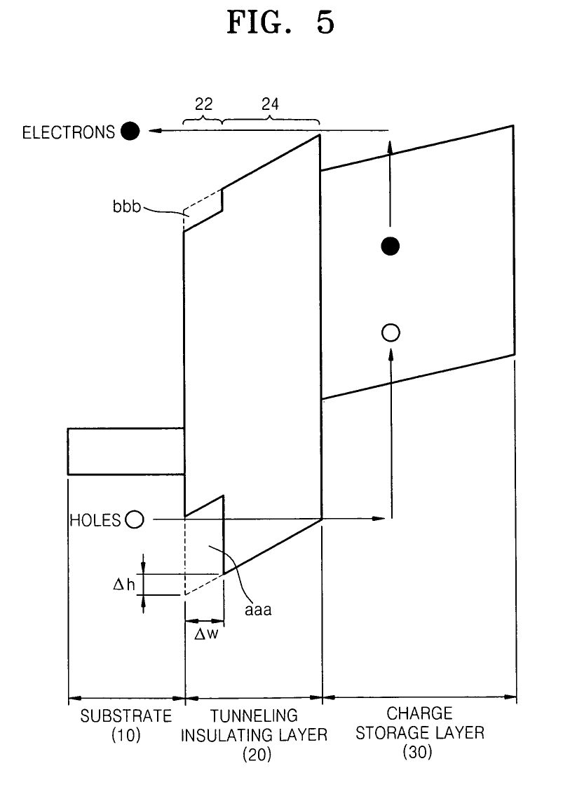

FIG. 3 illustrates an energy band model of the flash memory device 100 of FIG. 1. FIG. 4 illustrates an energy band model for describing a program operation of the flash memory device 100 of FIG. 1. FIG. 5 illustrates an energy band model for describing an erase operation of the flash memory device 100 of FIG. 1.

FIG. 3 illustrates the tunneling insulating layer 20 which may include the first region 22 formed of SiO₂ including nitrogen atoms and the second region 24 formed of SiO₂ not including nitrogen atoms. The substrate 10 may be a silicon substrate, and the charge storage layer 30 may be formed of Si₃N₄. An energy band gap of the tunneling insulating layer 20 may be greater than that of the charge storage layer 30. In a state where a voltage is not applied, for example, in an offset state, a conduction band difference between the tunneling insulating layer 20 and the charge storage layer 30 may be about 1.2 eV, and a balance band difference therebetween may be about 2.7 eV. As the first region 22 includes nitrogen atoms, the first region 22 may have an energy band in which a gap between the conduction band and the balance band may be reduced compared to the energy band of the SiO₂ film shown in a dotted line.

Regions a and b denote the balance band and the conduction band, respectively, that vary according to the content of nitrogen atoms within the first region 22. If there are more nitrogen atoms in the first region 22, there is less of a difference between the balance band and the conduction band. For example, if there are more nitrogen atoms in the first region 22 is, the energy level of the valence band is lower as well as that of the conduction band. Also, a variation of the balance band according to the content of nitrogen atoms may be relatively greater than that of the conduction band according to the content of nitrogen atoms. Sizes of the regions a and b in a width direction of the tunneling insulating layer 20 correspond to a width of the first region 22, e.g., a thickness of a layer including nitrogen atoms.

FIG. 4 illustrates a variation of an energy band when a program voltage may be applied to the flash memory device 100 of FIG. 1. The shapes of the energy bands of the tunneling insulating layer 20 and the charge storage layer 30 may vary according to the applied program voltage. Electrons stored in the substrate 10 may move to the charge storage layer 30 via the tunneling insulating layer 20 by the applied program voltage. As the first region 22 includes nitrogen atoms, a balance band of the first region 22 may have an energy level in which a region aa may decrease (for example, an energy level of the balance band may decrease), and a conduction band thereof may have an energy level in which a region bb decreases (for example, an energy level of the conduction band may decrease).

FIG. 5 illustrates a variation of an energy band when an erase voltage may be applied to the flash memory device 100 of FIG. 1. The shapes of the energy bands of the tunneling insulating layer 20 and the charge storage layer 30 may vary according to the applied erase voltage. Electrons stored in the charge storage layer 30 may move to the substrate 10 via the tunneling insulating layer 20 by the applied erase voltage. As the first region 22 includes nitrogen atoms, a balance band of the first region 22 may have an energy level in which a region aaa may decrease (for example, an energy level of the balance band may decrease), and a conduction band thereof may have an energy level in which a region bbb may decrease (for example, an energy level of the conduction band may decrease). Similarly to the actions performed during the above-described program operation, the electrons may more easily move by the decreased energy level of the conduction band. However, upon the erase operation, hole carriers of the substrate 10 may move to the charge storage layer 30 via the tunneling insulating layer 20. Because the variation of the energy level of the balance band is greater than that of the conduction band according to the nitrogen atomic content, the hole movement may be more affected than the electron movement. For example, an energy barrier of the balance band may decrease by a height of ΔH, and a width of the balance band may be ΔW. The decreased width ΔW corresponds to a width of the first region 22 including nitrogen atoms. Because the energy barrier of the balance band is decreased, the holes may move from the substrate 10 to the charge storage layer 30 with more ease and at a lower applied voltage upon the erase operation than upon program operation, and accordingly, the erase operation characteristics, may improve.

The improvement of the erase operation characteristics caused by the increase of hole mobility due to the nitrogen atomic content may be noticeable, especially in a charge trap flash (CTF) memory device. Unlike floating gates using a conductor as a material for forming the charge storage layer 30, CTF memory devices may use an insulator, for example, a Si₃N₄ film or quantum dots, in order to form the charge storage layer 30, thereby trapping electrons in a valley of an energy band. Therefore, once electrons are trapped, the electrons may not easily get out of the charge storage layer 30. Accordingly, a leakage current of CTF memory devices may be reduced, however, the erase operation characteristics of CTF memory devices may be deteriorated. However, a flash memory device according to example embodiments may increase the mobility of holes stored in a substrate instead of increasing the mobility of the trapped electrons, and thus, the erase operation may be performed. According to the flash memory device of example embodiments, current leakage may be prevented or reduced, and also the erase operation characteristics may improve.

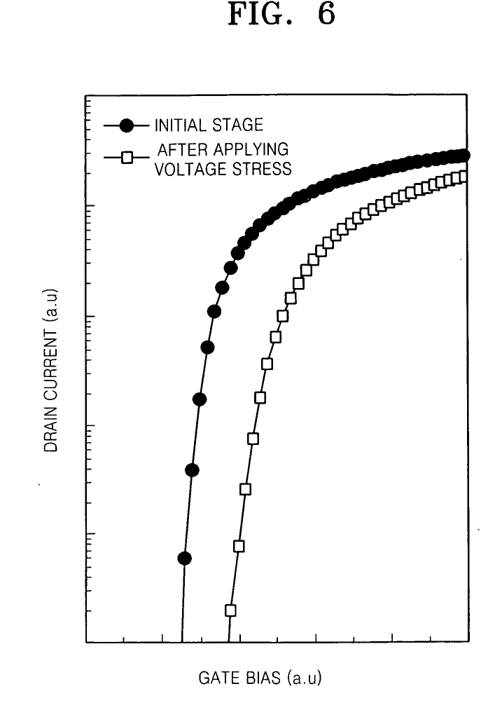

FIG. 6 is a graph illustrating characteristics of a gate bias and a drain current after applying a voltage stress to a flash memory device including a floating gate having a nitrogen atomic percent of more than about 5% according to a comparative example with respect to example embodiments.

Referring to FIG. 6, after a voltage stress is applied (for example, after repeatedly applying a program voltage and an erase voltage), a relationship between the drain current and the gate bias was changed as compared to an initial relationship therebetween. Consequently, in the floating gate structure, a nitride layer formed in a tunneling insulating layer may trap electrons, and thus, a program/erase voltage may increase. Therefore, even in the flash memory device using a floating gate according to the comparative example, when nitrogen atoms may be included in the tunneling insulating layer in order to increase program and erase operation characteristics, a percentage of the nitrogen atoms included in the tunneling insulating layer may be limited to no more than 5%. For example, when the percentage of the nitrogen atoms included in the floating gate may be more than 5%, the gate bias may increase due to an increase of negative charges stored in the floating gate, leading to deterioration of the floating gate.

However, in the flash memory device according to example embodiments, where nitrogen atoms are accumulated in a region adjacent to a substrate from the entire area of a tunneling insulating layer, characteristics of the flash memory device, namely, program and erase operation characteristics and leakage current characteristics, improved. When a height of the region, e.g., a first region 22, where the nitrogen atoms are accumulated is less than or equal to a half of the height of the tunneling insulating layer 20, the flash memory device had improved device characteristics. Also, when the height of the first region 22 is less than or equal to a third of the height of the tunneling insulating layer 20, the flash memory device had improved device characteristics than where the height of the first region 22 may be less than or equal to the third of the height of the tunneling insulating layer 20. Also, when a percentage of the nitrogen atoms included in the first region 22 may be in the range of about 1 to about 30%, the flash memory device had improved device characteristics. When the percentage of the nitrogen atoms included in the first region 22 may be in the range of about 5 to about 15%, the flash memory device had improved device characteristics than where the percentage of the nitrogen atoms included in the first region 22 may be in the range of about 1 to about 30%.

The percentage of the nitrogen atoms included in a second region 24 may be relatively low, e.g., lower than the percentage of the nitrogen atoms included in the first region 22. If the percentage of the nitrogen atoms included in a region adjacent to the charge storage layer 30, e.g., the second region 24, may be relatively low, a loss of the charges due to tunneling induced by charge trapping or charge binding generated in the second region 24 may decrease, and thus, retention characteristics of the charges may improve. Also, if the percentage of the nitrogen atoms included in the first region 22 is relatively high, a charge tunneling barrier of the tunneling insulating layer 20 may be lowered. Therefore, an erase speed may effectively increase according to an increase of a tunneling current, and thus, deterioration of the tunneling insulating layer 20 may decrease. Accordingly, retention characteristics of the device may improve.

The flash memory device according to example embodiments may decrease an applied voltage and may facilitate movement of carriers by including nitrogen atoms in a tunneling insulating layer and varying energy levels of a conduction band and a balance band. Thus, the flash memory device may perform a program/erase operation at increased speed.

Also, because the nitrogen atoms may be accumulated in a region adjacent to a substrate not in the entire area of the tunneling insulating layer, a thickness of the tunneling insulating layer may not need to be reduced in order to improve operation characteristics of the flash memory device. Therefore, an increase of a leakage current due to the thickness of a relatively thin tunneling insulating layer may be prevented or reduced, and accordingly, the flash memory device may have improved data retention. Because the flash memory device according to example embodiments facilitates movement of hole carriers, CTF memory devices may still have improved erase operation characteristics although electron movement may be difficult during an erase operation.

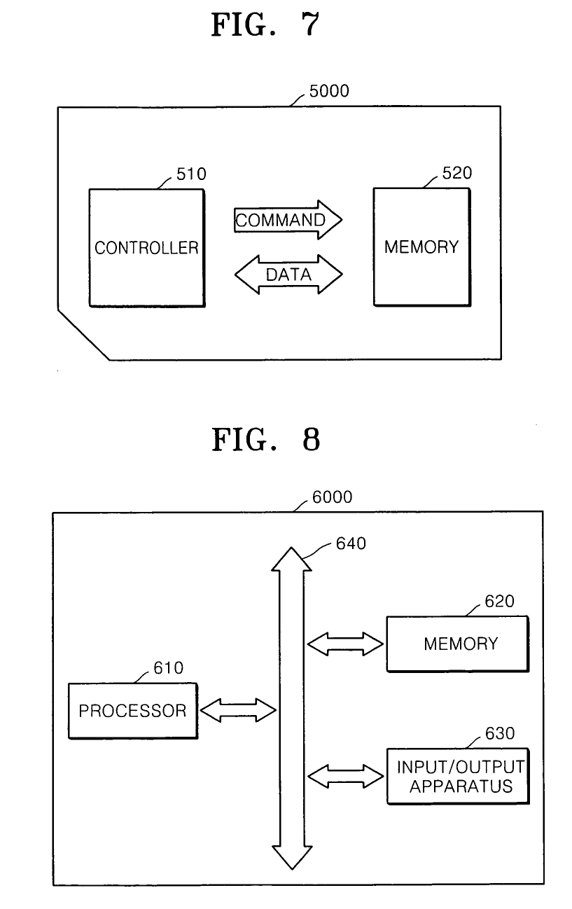

FIG. 7 is a schematic view of a memory card 5000 according to example embodiments. Referring to FIG. 7, a controller 510 and a memory 520 may be disposed to communicate via electrical signals. For example, when the controller 510 gives a command to the memory 520, the memory 520 may send data to the controller 510. The memory 520 may include the flash memory device 100 of FIG. 1. Flash memory devices according to example embodiments may be NAND or NOR architecture memory arrays (not shown) corresponding to logic gate designs, as generally known in the technical field. Each memory array may be comprised of a plurality of rows and columns which may have one or more memory array bank (not shown). The memory 520 may include the memory array (not shown) or the memory array bank (not shown). The memory card 5000 may further include a conventional row decoder (not shown), a conventional column decoder (not shown), conventional input/output (I/O) buffers (not shown), and/or a conventional control register (not shown) in order to drive the memory array bank (not shown). The memory card 5000 may be used in memory devices, e.g., various types of memory cards, for example, a memory stick card, a smart media (SM) card, a secure digital (SD) card, a mini SD card, or a multi-media card (MMC).

FIG. 8 is a schematic view illustrating a system 6000 according to example embodiments. Referring to FIG. 8, a processor 610, an input/output (I/O) apparatus 630, and a memory 620 may perform data communication using a bus 640. The processor 610 may execute a program and may control the system 6000. The input/output apparatus 630 may be used to input or output data of the system 6000. The system 6000 may be connected to an external apparatus, for example, a personal computer or a network, via the input/output apparatus 630, so as to send and receive data to and from the external apparatus. The memory 620 may include the flash memory device 100 of FIG. 1. For example, the memory 620 may store codes and data for operating the processor 610. For example, the system 6000 may be used in a mobile phone, a MP3 player, a navigation system, a portable multimedia player (PMP), a solid state disk (SSD), or a household appliance.

The foregoing is illustrative of example embodiments and is not to be construed as limiting thereof. Although example embodiments have been described, those skilled in the art will readily appreciate that many modifications are possible in example embodiments without materially departing from the novel teachings and advantages of example embodiments. Accordingly, all such modifications are intended to be included within the scope of the claims. Therefore, it is to be understood that the foregoing is illustrative of example embodiments and is not to be construed as limited to the specific embodiments disclosed, and that modifications to the disclosed embodiments, as well as other embodiments, are intended to be included within the scope of the appended claims. Example embodiments are defined by the following claims, with equivalents of the claims to be included therein.

What is claimed is:

1. A tunneling insulating layer including a first region and a second region on the first region, wherein the first region has a first nitrogen atomic percent, the second region has a second nitrogen atomic percent, and the second nitrogen atomic percent is less than the first nitrogen atomic percent.

2. The tunneling insulating layer of claim 1, wherein the first nitrogen atomic percent is in the range of about 1 to about 30%.

3. The tunneling insulating layer of claim 1, wherein the first nitrogen atomic percent is in the range of about 5 to about 15%.

4. The tunneling insulating layer of claim 1, wherein the second nitrogen atomic percent is in the range of about 0.01 to about 5%.

5. The tunneling insulating layer of claim 1, wherein the first region has a height that is less than or equal to a half of the height of the tunneling insulating layer.

6. The tunneling insulating layer of claim 1, wherein the first region has a height that is less than or equal to a third of the height of the tunneling insulating layer.

7. The tunneling insulating layer of claim 1, wherein the first region is a single layer including silicon oxynitride (SiON).

8. The tunneling insulating layer of claim 1, wherein the first region is formed of multiple layers including at least two materials selected from the group consisting of silicon oxide (SiO₂), silicon nitride (Si₃N₄), and silicon oxynitride (SiON).

9. The tunneling insulating layer of claim 1, wherein the second region includes one selected from the group consisting of silicon oxide (SiO₂) and silicon oxynitride (SiON), or a combination of two or more materials.

10. The tunneling insulating layer of claim 1, wherein one or both of the first region and the second region include an oxide film including at least one of a chemical vapor deposition (CVD) oxide film, a CVD nitride film, a thermal oxide film, and a thermal nitride film.

11. A flash memory device comprising:
a substrate including source and drain regions and a channel region between the source and drain regions;
the tunneling insulating layer of claim 1 on the channel region;
a charge storage layer on the tunneling insulating layer;
a blocking insulation layer on the charge storage layer; and
a gate electrode on the blocking insulation layer.

12. The flash memory device of claim 11, wherein an energy band gap of the tunneling insulating layer is greater than an energy band gap of the charge storage layer.

13. The flash memory device of claim 11, wherein the charge storage layer includes a charge trap layer for trapping charges.

14. The flash memory device of claim 13, wherein the charge trap layer includes at least one selected from the group consisting of a silicon oxide (SiO₂) layer, a silicon oxynitride (SiON), a silicon nitride (Si₃N₄) layer, Si rich nitride (SRN) layer, aluminum oxide (Al₂O₃) layer, an aluminum nitride (AlN) layer, a hafnium oxide (HfO₂) layer, a hafnium silicon oxide (HfSiO) layer, a hafnium silicon oxynitride (HfSiON) layer, a hafnium oxynitride (HfON) layer, a hafnium aluminum oxide layer (HfAlO), a zirconium oxide (ZrO₂) layer, a tantalum oxide (Ta₂O₃) layer, a hafnium tantalum oxide (HfTaₓO_{y}) layer, a lanthanum oxide (LaO) layer, lanthanum aluminum oxide (LaAlO) layer, a lanthanum hafnium oxide layer (LaHfO), and a combination thereof.

15. The flash memory device of claim 13, wherein the charge trap layer further comprises quantum dots.

16. The flash memory device of claim 15, wherein the quantum dots include at least one selected from the group consisting of silicon-quantum dots, germanium-quantum dots, tin-quantum dots, and gold-quantum dots, or a combination thereof.

17. The flash memory device of claim 11, wherein the blocking insulation layer includes at least one selected from the group consisting of a silicon oxide (SiO₂) layer, a silicon oxynitride (SiON), a silicon nitride (Si₃N₄) layer, Si rich nitride (SRN) layer, aluminum oxide (Al₂O₃) layer, an aluminum nitride (AlN) layer, a hafnium oxide (HfO₂) layer, a hafnium silicon oxide (HfSiO) layer, a hafnium silicon oxynitride (HfSiON) layer, a hafnium oxynitride (HfON) layer, a hafnium aluminum oxide layer (HfAlO), a zirconium oxide (ZrO₂) layer, a tantalum oxide (Ta₂O₃) layer, a hafnium tantalum oxide (HfTaₓO_{y}) layer, a lanthanum oxide (LaO) layer, lanthanum aluminum oxide (LaAlO) layer, a lanthanum hafnium oxide layer (LaHfO), and a combination thereof.

18. The flash memory device of claim 11, wherein the gate electrode includes at least one selected from the group consisting of poly-silicon, Al, Ru, TaN, TiN, W, WN, HfN, and WSi, or a combination thereof.

19. The flash memory device of claim 11, wherein the substrate includes one selected from the group consisting of silicon, silicon-on-insulator, silicon-on-sapphire, germanium, silicon-germanium, and gallium-arsenide, or a combination thereof.

20. A memory card comprising:
a memory including the flash memory device according to claim 11; and
a controller configured to control the memory, including sending and receiving data to and from the memory.

21. A system comprising:
a memory including the flash memory device according to claim 11; and
a processor configured to send and receive data to and from the memory via a bus; and
an input/output device configured to send and receive data to and from the bus.
